(19) United States
(12) Patent Application Publication
(10) Pub. No.: US 2024/0002757 A1
(43) Pub. Date: Jan. 4, 2024

(54) SELF-ASSEMBLED MONOLAYER REMOVING LIQUID, AND SUBSTRATE TREATING METHOD AND SUBSTRATE TREATING APPARATUS USING THE SAME

(71) Applicant: Screen Holdings Co., Ltd., Kyoto (JP)

(72) Inventors: Yukifumi YOSHIDA, Kyoto (JP); Yasuharu MIYAMOTO, Kyoto (JP)

(21) Appl. No.: 18/333,736

(22) Filed: Jun. 13, 2023

(30) Foreign Application Priority Data
Jun. 30, 2022 (JP) 2022-106030

(51) Int. Cl. C11D 7/50; C11D 11/00; C11D 7/26; B08B 3/08

(52) U.S. Cl. CPC C11D 7/5022; C11D 11/0047; C11D 7/267; C11D 7/261; B08B 3/08; H01L 21/0206

(57) ABSTRACT

The present invention is a self-assembled monolayer removing liquid for selectively removing a self-assembled monolayer provided on a surface of a substrate, the removing liquid having a Hansen solubility parameter positioned in a first Hansen sphere of a material for forming the self-assembled monolayer and in a second Hansen sphere of the self-assembled monolayer, the first Hansen sphere being defined by a center value (δd₁, δp₁, δh₁) [MPa^{1/2}] and a sphere radius R₁ [MPa^{1/2}] in a Hansen solubility parameter space, the second Hansen sphere being defined by a center value (δd₂, δp₂, δh₂) [MPa^{1/2}] and a sphere radius R₂ [MPa^{1/2}] in the Hansen solubility parameter space.

### FIELD OF THE INVENTION

The present invention relates to a self-assembled monolayer removing liquid capable of selectively removing a self-assembled monolayer provided on a surface of a substrate, and a substrate treating method and a substrate treating apparatus using the removing liquid.

### BACKGROUND OF THE INVENTION

In the manufacture of semiconductor devices, photolithography techniques are widely used as techniques for selectively forming films in a specific surface region of a substrate. For example, an insulating film is formed after a lower layer wiring is formed, a dual damascene structure having a trench and a via hole is formed by photolithography and etching, and a conductive film such as Cu is embedded in the trench and the via hole to form a wiring.

In recent years, however, with increasing progress in miniaturization of semiconductor devices, photolithography techniques do not afford sufficient alignment accuracy in some cases. For this reason, a technique of selectively forming a film with high accuracy in a specific region on a substrate surface is required to replace photolithography techniques.

For example, U.S. Pat. No. 10,867,850 discloses a film forming method in which a self-assembled monolayer (SAM) is formed on a surface of a substrate region where film formation is not desired, and a film is selectively formed on the substrate region where the SAM is not formed. This patent document also discloses that the SAM is removed by using acetic acid after selective film formation.

The film forming method disclosed in this patent document, however, has a problem that selective removal of SAM with acetic acid is insufficient.

### SUMMARY OF THE INVENTION

The present invention has been made in view of the above problems, and an object of the present invention is to provide a self-assembled monolayer removing liquid capable of selectively removing a self-assembled monolayer provided on a surface of a substrate, and a substrate treating method and a substrate treating apparatus using the removing liquid.

To solve the above problem, the self-assembled monolayer removing liquid of the present invention is a self-assembled monolayer removing liquid for selectively removing a self-assembled monolayer provided on a surface of a substrate, the self-assembled monolayer removing liquid having a Hansen solubility parameter positioned in a first Hansen sphere of a material for forming the self-assembled monolayer and in a second Hansen sphere of the self-assembled monolayer, the first Hansen sphere being defined by a center value (δd₁, δp₁, δh₁) [MPa^{1/2}] and a sphere radius R, [MPa^{1/2}] in a Hansen solubility parameter space, the second Hansen sphere being defined by a center value (δd₂, δp₂, δh₂) [MPa^{1/2}] and a sphere radius R₂ [MPa^{1/2}] in the Hansen solubility parameter space.

The first Hansen sphere in the above configuration is defined by the Hansen solubility parameters of the material for forming the self-assembled monolayer in a Hansen solubility parameter space. Since the Hansen solubility parameters of the self-assembled monolayer removing liquid is in the first Hansen sphere, the self-assembled monolayer removing liquid has high affinity for the constituent molecules of the self-assembled monolayer and has a good dissolving property. Thus, the self-assembled monolayer removing liquid can dissolve the self-assembled monolayer well and remove the monolayer from the surface of the substrate. The second Hansen sphere in the above configuration is defined by the Hansen solubility parameters of the self-assembled monolayer in the Hansen solubility parameter space. Since the Hansen solubility parameters of the self-assembled monolayer removing liquid is in the second Hansen sphere, the self-assembled monolayer removing liquid has high affinity for the self-assembled monolayer and has good wettability. Thus, when the self-assembled monolayer removing liquid comes into contact with the self-assembled monolayer, the self-assembled monolayer removing liquid can wet well the self-assembled monolayer and can spread on the surface of the self-assembled monolayer, which makes it possible to further promote the removal of the self-assembled monolayer through dissolving.

That is, the self-assembled monolayer removing liquid having the above configuration has a good dissolving property with respect to the self-assembled monolayer and good wettability, and thus, for example, the removing liquid can exhibit excellent removal performance with respect to the self-assembled monolayer as compared with a conventional self-assembled monolayer removing liquid having only a good dissolving property.

In the above configuration, the Hansen solubility parameter of the self-assembled monolayer removing liquid preferably has a value positioned at a center of a circle formed by an intersection of the first Hansen sphere and the second Hansen sphere or has a value positioned at a contact point between the first Hansen sphere and the second Hansen sphere. This makes it possible to provide a self-assembled monolayer removing liquid having an excellent balance between the dissolving property and wettability with respect to the self-assembled monolayer and having further excellent removal performance with respect to the self-assembled monolayer.

In the above configuration, the material for forming the self-assembled monolayer may be octadecylphosphonic acid, the self-assembled monolayer may include a monolayer of the octadecylphosphonic acid, the first Hansen sphere may be defined by the center value (δd₁, δp₁, δh₁)=(16.9±0.2, 5.4±0.5, 11.7±0.3) [MPa^{1/2}] and the sphere radius R₁=3.7 [MPa^{1/2}] in the Hansen solubility parameter space, and the second Hansen sphere may be defined by the center value (δd₂, δp₂, δh₂)=(16.4±0.7, 6.1±1.2, 0.0±2.0) [MPa^{1/2}] and the sphere radius R₂=10.2 [MPa²] in the Hansen solubility parameter space.

With the above configuration, by setting the Hansen solubility parameter of the self-assembled monolayer removing liquid to be in the first Hansen sphere defined by the center value (δd₁, δp₁, δh₁)=(16.9±0.2, 5.4±0.5, 11.7±0.3) [MPa^{1/2}] and the sphere radius R₁=3.7 [MPa^{1/2}] and in the second Hansen sphere defined by the center value (δd₂, δp₂, δh₂)=(16.4±0.7, 6.1±1.2, 0.0±2.0) [MPa^{1/2}] and the sphere radius R₂=10.2 [MPa^{1/2}], not only the affinity of the self-assembled monolayer removing liquid for octadecylphosphonic acid is increased and the dissolving property is improved, but also the affinity of the self-assembled monolayer removing liquid for the monolayer of octadecylphosphonic acid is increased and wettability is improved. Thus, the self-assembled monolayer removing liquid having the above configuration can exhibit excellent removal performance as compared with, for example, a conventional self-assembled monolayer removing liquid having only a good dissolving property with respect to a monolayer of octadecylphosphonic acid.

In the above configuration, the self-assembled monolayer removing liquid is preferably at least one organic solvent selected from a group consisting of 1-butanol, 2-butanol, 1-pentanol, tetrahydrofuran, and benzyl alcohol.

To solve the above problem, the substrate treating method of the present invention is a substrate treating method for treating a substrate provided with a self-assembled monolayer on a surface, the method including a preparing step of preparing a self-assembled monolayer removing liquid for selectively removing the self-assembled monolayer from the substrate and a removing step of bringing the self-assembled monolayer removing liquid into contact with the self-assembled monolayer and selectively removing the self-assembled monolayer from the substrate, wherein the preparing step is a step of preparing the self-assembled monolayer removing liquid having a Hansen solubility parameter positioned in a first Hansen sphere of a material for forming the self-assembled monolayer and in a second Hansen sphere of the self-assembled monolayer, the first Hansen sphere being defined by a center value (δd₁, δp₁, δh₁) [MPa^{1/2}] and a sphere radius R₁ [MPa^{1/2}] in a Hansen solubility parameter space, the second Hansen sphere being defined by a center value (δd₂, δp₂, δh₂) [MPa^{1/2}] and a sphere radius R₂ [MPa^{1/2}] in the Hansen solubility parameter space.

According to the above configuration, in the step of preparing the self-assembled monolayer removing liquid, the self-assembled monolayer removing liquid is provided, for example, by preparing a self-assembled monolayer removing liquid having a Hansen solubility parameter positioned in the first Hansen sphere and in the second Hansen sphere. The first Hansen sphere is defined by the Hansen solubility parameter of the material for forming the self-assembled monolayer, and the second Hansen sphere is defined by the Hansen solubility parameter of the self-assembled monolayer. Thus, the self-assembled monolayer removing liquid not only exhibits a good dissolving property with respect to the self-assembled monolayer but also has good wettability. Therefore, in the treating method having the above configuration, when the self-assembled monolayer removing liquid comes into contact with the self-assembled monolayer, the self-assembled monolayer removing liquid can wet well the self-assembled monolayer and can spread on the surface of the self-assembled monolayer, and thus the removing liquid can more favorably remove the self-assembled monolayer through dissolving as compared with a conventional treating method in which a self-assembled monolayer removing liquid having only a good dissolving property is used, for example.

In the above configuration, the preparing step is preferably a step of preparing the self-assembled monolayer removing liquid to cause the Hansen solubility parameter of the self-assembled monolayer removing liquid to have a value positioned at a center of a circle formed by an intersection of the first Hansen sphere and the second Hansen sphere or have a value positioned at a contact point between the first Hansen sphere and the second Hansen sphere. This makes it possible to prepare a self-assembled monolayer removing liquid having an excellent balance between the dissolving property and wettability with respect to the self-assembled monolayer. As a result, the self-assembled monolayer can be further favorably removed.

In the above configuration, the material for forming the self-assembled monolayer may be octadecylphosphonic acid, the self-assembled monolayer may include a monolayer of the octadecylphosphonic acid, the first Hansen sphere may be defined by the center value (δd₁, δp₁, δh₁)=(16.9±0.2, 5.4±0.5, 11.7±0.3) [MPa^{1/2}] and the sphere radius R₁=3.7 [MPa^{1/2}] in the Hansen solubility parameter space, and the second Hansen sphere may be defined by the center value (δd₂, δp₂, δh₂)=(16.4±0.7, 6.1±1.2, 0.0±2.0) [MPa^{1/2}] and the sphere radius R₂=10.2 [MPa^{1/2}] in the Hansen solubility parameter space.

According the above configuration, as the self-assembled monolayer removing liquid, a self-assembled monolayer removing liquid with a Hansen solubility parameter positioned in the first Hansen sphere defined by the center value (δd₁, δp₁, δh₁)=(16.9±0.2, 5.4±0.5, 11.7±0.3) [MPa^{1/2}] and the sphere radius R₁=3.7 [MPa^{1/2}] and in the second Hansen sphere defined by the center value (δd₂, δp₂, δh₂)=(16.4±0.7, 6.1±1.2, 0.0±2.0) [MPa^{1/2}] and the sphere radius R₂=10.2 [MPa^{1/2}] is used. As a result, the self-assembled monolayer removing liquid not only exhibits a good dissolving property but also has good wettability with respect to the monomolecular film of octadecylphosphonic acid, and thus, selective removal of the monomolecular film of octadecylphosphonic acid can be favorably performed as compared with a substrate treating method in which a conventional self-assembled monolayer removing liquid having only a good dissolving property is used.

In the above configuration, the self-assembled monolayer removing liquid is preferably at least one organic solvent selected from a group consisting of 1-butanol, 2-butanol, 1-pentanol, tetrahydrofuran, and benzyl alcohol.

To solve the above problem, the substrate treating apparatus of the present invention is a substrate treating apparatus for treating a substrate provided with a self-assembled monolayer on a surface, the substrate treating apparatus including a storage unit that stores a self-assembled monolayer removing liquid for selectively removing the self-assembled monolayer, a supply unit that supplies the self-assembled monolayer removing liquid to a surface of a substrate and selectively removes the self-assembled monolayer from the surface of the substrate, and a control unit that controls supply of the self-assembled monolayer removing liquid to the surface of the substrate, wherein the control unit prepares, in the storage unit, as the self-assembled monolayer removing liquid, a self-assembled monolayer removing liquid having a Hansen solubility parameter positioned in a first Hansen sphere of a material for forming the self-assembled monolayer and in a second Hansen sphere of the self-assembled monolayer, the first Hansen sphere being defined by a center value (δd₁, δp₁, δh₁) [MPa^{1/2}] and a sphere radius R₁ [MPa^{1/2}] in a Hansen solubility parameter space, the second Hansen sphere being defined by a center value (δd₂, δp₂, δh₂) [MPa^{1/2}] and a sphere radius R₂ [MPa^{1/2}] in the Hansen solubility parameter space.

According to the above configuration, the supply unit supplies the self-assembled monolayer removing liquid stored in the storage unit to a surface of a substrate under the control of the control unit. Then, w % ben the self-assembled monolayer removing liquid comes into contact with the self-assembled monolayer provided on the surface of the substrate, the removing liquid dissolves and removes the self-assembled monolayer. Here, the control unit prepares the self-assembled monolayer removing liquid stored in the storage unit in such a manner that the self-assembled monolayer removing liquid has a Hansen solubility parameter positioned in the first Hansen sphere and in the second Hansen sphere. As a result, the self-assembled monolayer removing liquid to be supplied to the substrate not only exhibits a good dissolving property but also has good wettability with respect to the self-assembled monolayer. As a result, according to the above configuration, it is possible to provide a substrate treating apparatus that enables favorable selective removal of a self-assembled monolayer as compared with a conventional substrate treating apparatus that prepares and supplies a self-assembled monolayer removing liquid having only a good dissolving property, for example.

The present invention can provide a self-assembled monolayer removing liquid capable of selectively and preferably removing a self-assembled monolayer as a protective film, and a substrate treating method and a substrate treating apparatus using the removing liquid.

### BRIEF DESCRIPTION OF THE FIGURES

FIG. 1 is an explanatory diagram showing Hansen solubility parameters of a self-assembled monolayer removing liquid according to an embodiment of the present invention in a Hansen solubility parameter space;

FIG. 2 is a flowchart showing an example of an overall flow of a substrate treating method according to an embodiment of the present invention;

FIG. 3A is a schematic view depicting an example of a state change of a substrate in a film forming method according to an embodiment of the present invention, showing a state in which a material for forming a self-assembled monolayer is supplied to a substrate surface;

FIG. 3B is a schematic view depicting an example of a state change of a substrate in a film forming method according to an embodiment of the present invention, showing a state in which a self-assembled monolayer is formed in a metal-film-forming region of a substrate surface;

FIG. 3C is a schematic view depicting an example of a state change of a substrate in a film forming method according to an embodiment of the present invention, showing a state in which a film is formed in a metal-film-free region of a substrate surface;

FIG. 3D is a schematic view depicting an example of a state change of a substrate in a film forming method according to an embodiment of the present invention, showing a state in which a self-assembled monolayer in a metal-film-forming region of a substrate surface is removed;

FIG. 4 is an explanatory diagram schematically showing a supply device in a substrate treating apparatus according to an embodiment of the present invention; and

FIG. 5 is an explanatory diagram schematically showing a removing device in the substrate treating apparatus according to an embodiment of the present invention.

### DETAILED DESCRIPTION OF THE INVENTION

The present invention has been made with the finding that using a self-assembled monolayer removing liquid (hereinafter “removing liquid”) that selectively removes a self-assembled monolayer (SAM) provided on a surface of a substrate, the removing liquid having an excellent balance between the dissolving property and wettability with respect to the SAM, achieving a good removal performance as compared with a conventional removing liquid. Here, the solubility of the SAM increases as the affinity between the removing liquid and the material for forming the SAM increases. The wettability with respect to the SAM increases as the affinity between the removing liquid and the SAM increases. In the present invention, Hansen solubility parameter (HSP) at any temperature is used as an index indicating affinity with a SAM or a material for forming a SAM.

HSP is an index of solubility indicating how much a solute dissolves in a solvent, and is used, for example, to predict solubility of a solute in a solvent. HSP is composed of the energy (δd) derived from dispersion forces between molecules, the energy (δp) derived from dipole intermolecular interaction between molecules, and the energy (δh) derived from hydrogen bonds between molecules. HSP may be defined by the following formula.

HSP value (δt)=(δd²+δp²+δh²)^{1/2}

These three parameters δd, δp, and δh may be regarded as coordinates in a three-dimensional space (Hansen solubility parameter space) including a δd axis, a δp axis, and a δh axis. In the Hansen solubility parameter space, the shorter the distance between (δdₘ, δpₘ, δhₘ) of a solute and (δdₙ, δpₙ, δhₙ) of a solvent, the higher the affinity for each other, indicating that the solute is more likely to be dissolved in the solvent.

### (Self-Assembled Monolayer Removing Liquid)

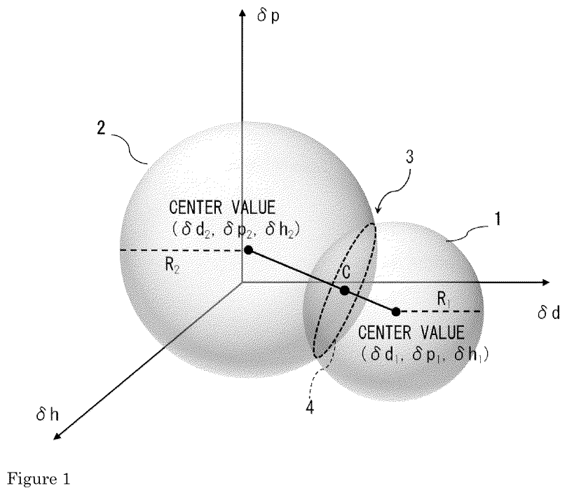

Next, a removing liquid according to the present embodiment will be described below with reference to FIG. 1. FIG. 1 is an explanatory diagram showing HSP of the removing liquid according to the present embodiment in a Hansen solubility parameter space.

The removing liquid of the present embodiment is used for selective removal of a SAM provided on a substrate surface. As shown in FIG. 1, the removing liquid of the present embodiment is a liquid whose HSP ((δd, δp, δh) [MPa^{1/2}]) is positioned in a first Hansen sphere 1 and in a second Hansen sphere 2 defined in the Hansen solubility parameter space.

The first Hansen sphere 1 means a Hansen sphere defined by the HSP of the material for forming the SAM in the Hansen solubility parameter space. More specifically, as shown in FIG. 1, the first Hansen sphere 1 is a Hansen sphere defined by a center value (δd₁, δp₁, δh₁) [MPa^{1/2}] and a sphere radius R₁ [MPa^{1/2}] in the Hansen solubility parameter space. The second Hansen sphere 2 means a Hansen sphere defined by the HSP of the SAM in the Hansen solubility parameter space. More specifically, as shown in FIG. 1, the second Hansen sphere 2 is a Hansen sphere defined by a center value (δd₂, δp₂, δh₂) [MPa^{1/2}] and a sphere radius R₂ [MPa^{1/2}] in the Hansen solubility parameter space. δd, δd₁, and δd₂ represent the energy from dispersion forces between molecules (dispersion term). δp, δp₁ and δp₂ represent the energy from dipole intermolecular interaction between molecules (polar term). δh, δh₁, and δh₂ represent the energy from hydrogen bonds between molecules (hydrogen bond term).

The HSP ((δd, δp, δh) [MPa^{1/2}]) of the removing liquid of the present embodiment is positioned in a region 3 where the first Hansen sphere 1 and the second Hansen sphere 2 overlap each other in the Hansen solubility parameter space. Thus, the removing liquid of the present embodiment exhibits good affinity for both the material for forming the SAM and the SAM. Thus, the removing liquid exhibits not only a good dissolving property with respect to the material for forming the SAM but also good wettability with respect to the SAM. This causes the removing liquid of the present embodiment to spread well on the SAM surface when the removing liquid comes into contact with the SAM than a conventional removing liquid does. As a result, for example, the removing liquid of the present embodiment has an improved selective removal performance for the SAM as compared with a conventional removing liquid that has a dissolving property only to the SAM.

Here, the removing liquid of the present embodiment is preferably a solvent whose HSP, that is, (δd, δp, δh) is positioned at a center C of a circle 4 formed by an intersection of the first Hansen sphere 1 and the second Hansen sphere 2 (see FIG. 1). Such a solvent has an excellent balance of the dissolving property to the material for forming the SAM and wettability to the SAM, exhibiting a good selective removal performance to the SAM. When the first Hansen sphere 1 and the second Hansen sphere 2 contact each other, (δd, δp, δh) of the removing liquid preferably has a value positioned at a contact point of the first Hansen sphere 1 and the second Hansen sphere 2.

The removing liquid of the present embodiment is subjected to no particular limitation as long as its HSP is in the region 3 where the first Hansen sphere 1 and the second Hansen sphere 2 overlap each other in the Hansen solubility parameter space. Specific examples of the removing liquid include at least one organic solvent selected from the group consisting of 1-butanol, 2-butanol, 1-pentanol, tetrahydrofuran (THF), and benzyl alcohol. As the removing liquid, these organic solvents may be selected and used in combination as appropriate according to the type of SAM. The removing liquid of the present embodiment preferably has no dissolving property with respect to a metal film, a film (details will be described later), or the like. When the removing liquid has a dissolving property with respect to a metal film, a film, and the like, the extent of the property is preferably not enough to generate a film formation defect such as excessive etching of the metal film, the film, and the like.

For example, when the SAM is composed of a monolayer of octadecylphosphonic acid, the first Hansen sphere 1 related to HSP (25° C.) of octadecyl phosphonic acid is defined by the center value (δd₁, δp₁, δh₁)=(16.9±0.2, 5.4±0.5, 11.7±0.3) [MPa^{1/2}] and the sphere radius R₁=3.7 [MPa^{1/2}] (δt₁=3.7 MPa^{1/2}). The second Hansen sphere 2 related to the HSP (25° C.) of the monolayer of octadecylphosphonic acid is defined by the center value (δd₂, δp₂, δh₂)=(16.4±0.7, 6.1±1.2, 0.0±2.0) [MPa^{1/2}] and the sphere radius R₂=10.2 [MPa^{1/2}] (δt₂=10.2 MPa^{1/2}). Thus, it can be said that the most suitable removing liquid for selectively removing the monolayer of octadecylphosphonic acid is a solvent having HSP of (δd, δp, δh)=(16.8, 5.6, 9.0). Examples of the removing liquid having such value of (δd, δp, δh) include a mixed solvent composed of THF, 1-butanol, and benzyl alcohol (volume ratio THF: 1-butanol:benzyl alcohol=8:1:1), a mixed solvent composed of THF, 2-butanol, and benzyl alcohol (volume ratio THF:2-butanol:benzyl alcohol=8:1:1), and a mixed solvent composed of THF, 1-pentanol, and benzyl alcohol (volume ratio THF:1-pentanol:benzyl alcohol=8:1:1).

The HSP of the organic solvents exemplified above are as follows.

TABLE 1

| | HSP(MPa^{1/2}) | | | |
|---|---|---|---|---|
| Solvent | δd | δp | δh | δt |
| 1-Butanol | 16.0 | 5.7 | 15.8 | 23.2 |
| 2-Butanol | 15.8 | 5.7 | 14.5 | 22.2 |
| 1-Pentanol | 15.9 | 5.9 | 13.9 | 21.9 |
| THF | 16.8 | 5.7 | 8.0 | 19.5 |
| Benzyl alcohol | 18.4 | 6.3 | 13.7 | 23.8 |

### (Substrate Treating Method)

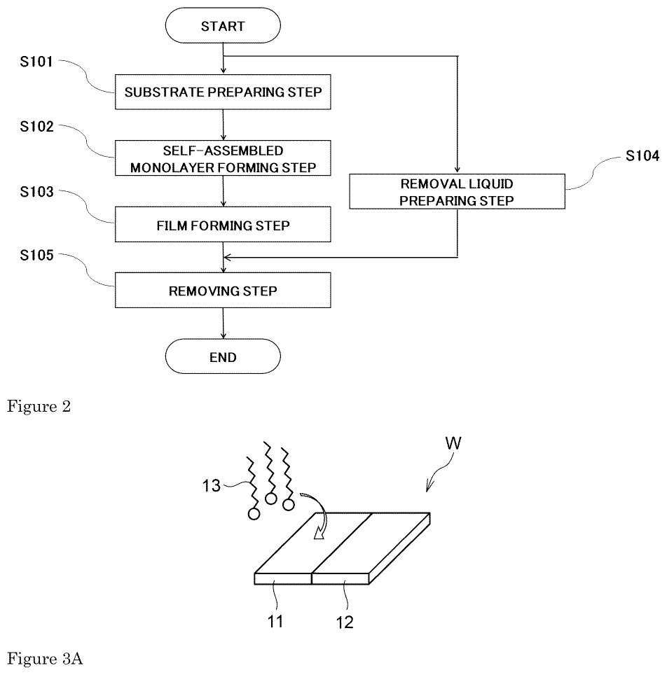

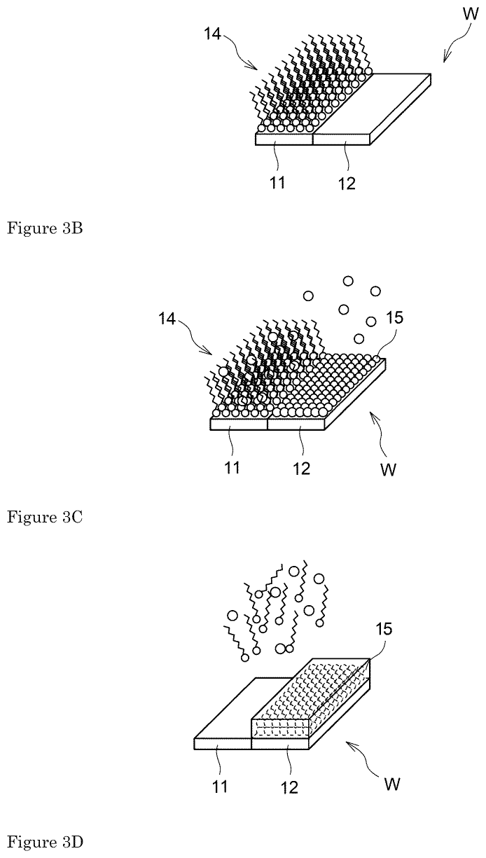

Next, a substrate treating method according to the present embodiment will be described below with reference to FIGS. 2 and 3A to 3D. FIG. 2 is a flowchart showing an example of an overall flow of the substrate treating method according to the embodiment of the present invention. FIGS. 3A to 3D are schematic views showing an example of a state change of a substrate in the film forming method according to an embodiment of the present invention, in which FIG. 3A shows a state in which a material for forming a self-assembled monolayer is supplied to a substrate surface. FIG. 3B shows a state in which a self-assembled monolayer is formed in a metal-film-forming region of a substrate surface, FIG. 3C shows a state in which a film is formed in a metal-film-free region of a substrate surface, and FIG. 3D shows a state in which a self-assembled monolayer in a metal-film-forming region of a substrate surface is removed.

The substrate treating method of the present embodiment provides a technique for selectively forming a film according to the material of a substrate surface when a film is formed on the surface of a substrate W. In the present specification, the “substrate” refers to various substrates such as a semiconductor substrate, a glass substrate for a photomask, a glass substrate for a liquid crystal display, a glass substrate for a plasma display, a substrate for a field emission display (FED), a substrate for an optical disk, a substrate for a magnetic disk, and a substrate for a magneto-optical disk.

As shown in FIG. 2, the substrate treating method of the present embodiment includes at least a substrate W preparing step S101, a self-assembled monolayer forming step S102 for forming a SAM, a film forming step S103, a removing liquid preparing step S104, and a SAM removing step S105.

As shown in FIGS. 2 and 3A, the substrate W provided in the substrate W preparing step S101 includes a metal-film-forming region formed by exposing a metal film 11 and a metal-film-free region formed by exposing an insulating film 12. More specifically, examples of the substrate W include a substrate including the insulating film 12 formed with a trench with any wiring width and the metal film 11 embedded in the trench. The step of preparing a substrate W may include, for example, loading the substrate W into a chamber (details will be described later) that is a container for accommodating the substrate W with a substrate loading/unloading mechanism.

Although one metal film formation region and one metal film-free region are formed in FIG. 3A, a plurality of metal-film-forming regions and a plurality of metal-film-free regions may be formed. For example, a band-shaped metal-film-free region may be disposed to be interposed between adjacent band-shaped metal-film-forming regions, or a band-shaped metal-film-forming region may be disposed to be interposed between adjacent band-shaped metal-film-free regions.

The substrate W of the present embodiment is not limited to the case where only the metal-film-forming region and the metal-film-free region are provided on its surface. For example, a region formed by exposing another film made of a material different from the material of the metal film 11 or the insulating film 12 to the surface may be provided. In this case, the position where the region is provided is subjected to no particular limitation, and any position may be set.

The metal film 11 is subjected to not particular limitation, and examples thereof include films made of copper (Cu), tungsten (W), ruthenium (Ru), germanium (Ge), silicon (Si), titanium nitride (TiN), cobalt (Co), molybdenum (Mo), and the like.

The insulating film 12 is subjected to no particular limitation, and examples thereof include films made of silicon oxide (SiO₂), hafnium oxide (HfO₂), zirconia (ZrO₂), silicon nitride (SiN), and the like.

The treating liquid used in the SAM forming step S102 includes at least a material for forming the SAM (hereinafter referred to as “SAM forming material”) and a solvent. The SAM forming material may be dissolved or dispersed in a solvent.

The SAM forming material is subjected to no particular limitation, and examples thereof include phosphonic acid compounds having a phosphonic acid group such as a monophosphonic acid and a diphosphonic acid. These phosphonic acid compounds may be used singly or as a mixture of two or more of the compounds.

The monophosphonic acid is subjected to no particular limitation, and examples thereof include a phosphonic acid compound represented by the general formula R—P(═O)(OH)₂, where R is an alkyl group represented by 1 to 18 carbon atoms, an alkyl group in the range of 1 to 18 carbon atoms and having a fluorine atom, or a vinyl group. In the present specification, when a range of the number of carbon atoms is shown, it means that the range includes the numbers of carbon atoms of all integers included in the range. Thus, for example, an alkyl group having “1 to 3 carbon atoms” means an alkyl group having 1, 2, or 3 carbon atoms.

The alkyl group represented by 1 to 18 carbon atoms may be either linear or branched. Further, the number of carbon atoms in the alkyl group is preferably in the range of 10 to 18, and more preferably in the range of 14 to 18. The alkyl group in the range of 1 to 18 carbon atoms and having a fluorine atom may be either linear or branched. Further, the number of carbon atoms in the alkyl group having a fluorine atom is preferably in the range of 10 to 18, and more preferably in the range of 14 to 18.

Specific examples of the monophosphonic acid represented by R—P(═O)(OH)₂ include a compound represented by any of the following chemical formulas (1) to (16).

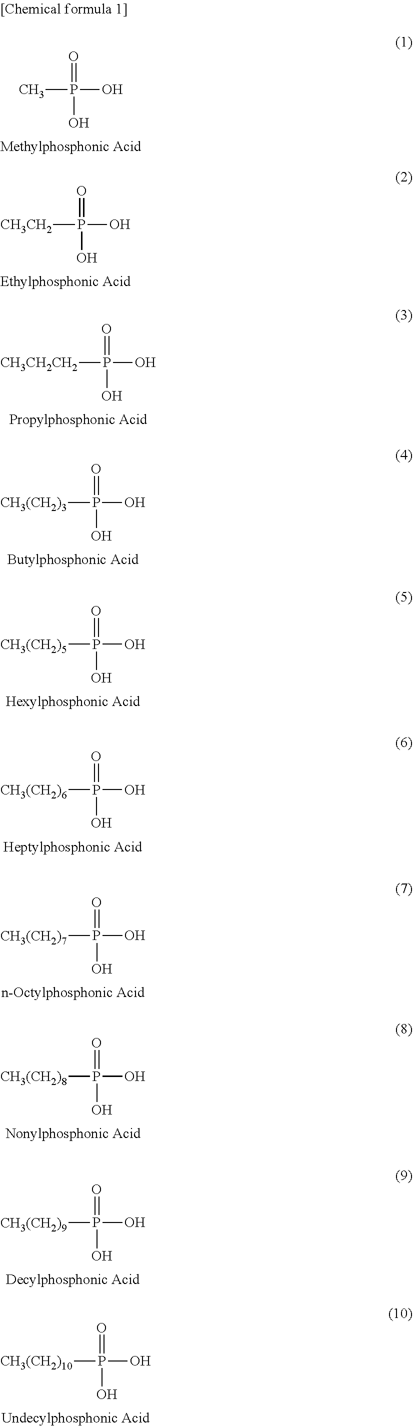

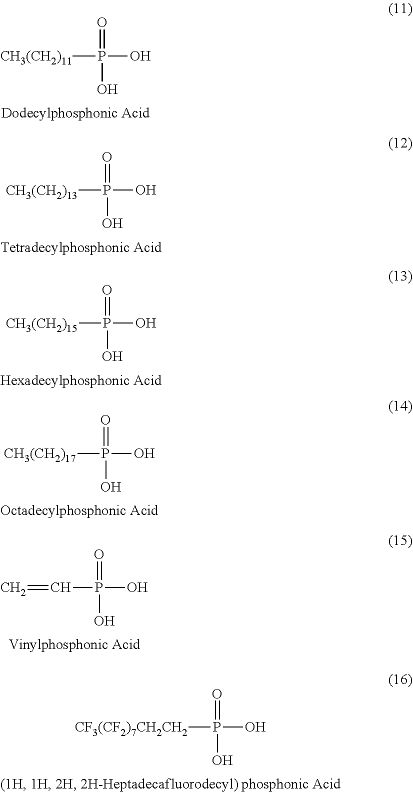

As the monophosphonic acid, in addition to those exemplified above, a compound represented by any of the following chemical formulas (17) to (19) may also be used.

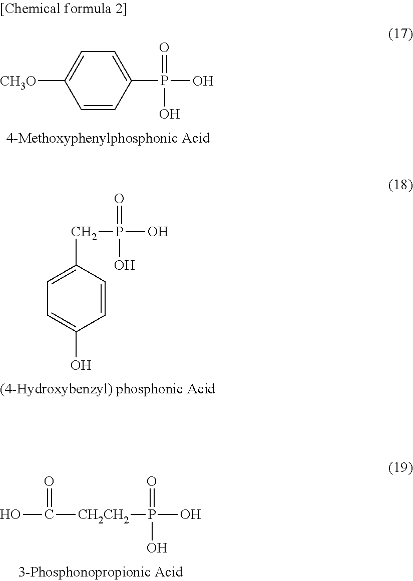

Examples of the diphosphonic acid include a compound represented by any of the following chemical formulas (20) and (21).

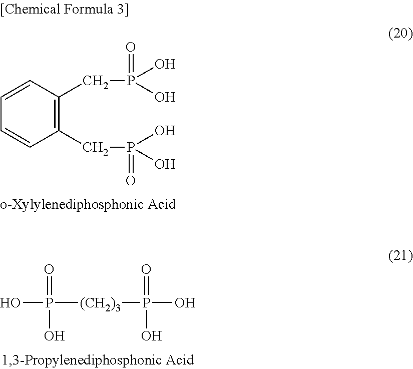

Of the exemplified phosphonic acid compounds, octadecylphosphonic acid or the like is preferable from the viewpoint of formation of a dense SAM.

The solvent in the treating liquid is subjected to no particular limitation, and examples thereof include an alcohol solvent, an ether solvent, a glycol ether solvent, and a glycol ester solvent. The alcohol solvent is subjected to no particular limitation, and examples thereof include ethanol. The ether solvent is subjected to no particular limitation, and examples thereof include tetrahydrofuran (THF). The glycol ether solvent is subjected to no particular limitation, and examples thereof include propylene glycol monomethyl ether (PGME). The glycol ester solvent is subjected to no particular limitation, and examples thereof include propylene glycol monomethyl ether acetate (PGMEA). These solvents may be used singly or as a mixture of two or more of the solvents. In addition, these solvents may be used in any combination with the above-described exemplified phosphonic acid compounds. Of the exemplified solvents, an alcohol solvent is preferable, and ethanol is particularly preferable from the viewpoint that a phosphonic acid compound can be dissolved.

The content of the SAM forming material 13 is preferably in the range of 0.0004 mass % to 0.2 mass %, more preferably in the range of 0.004 mass % to 0.08 mass %, and particularly preferably in the range of 0.02 mass % to 0.06 mass % with respect to the total mass of the treating liquid.

The treating liquid may contain a known additive as long as the effect of the present invention is not impaired. The additive is subjected to no particular limitation, and examples thereof include a stabilizer and a surfactant.

As shown in FIGS. 2, 3A, and 3B, the SAM forming step S102 is a step of forming a SAM 14 by bringing the treating liquid into contact with a surface of the substrate W and causing the SAM forming material 13 contained in the treating liquid to adsorb on the surface of the metal film 11. Here, the SAM 14 is selectively formed only on the metal film 11 in the metal film formation region of the substrate W and not formed in the metal-film-free region. The reason of the formation of the SAM 14 only on the metal film 11 is that when the metal film 11 is a Cu (copper) film, for example, the phosphonic acid group of the phosphonic acid compound serving as the SAM forming material 13 and the —OH group on the surface of the Cu film react with each other as expressed by the following chemical reaction formula.

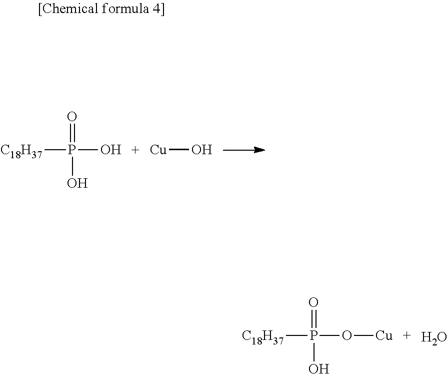

The method of bringing the treating liquid into contact with the substrate W is subjected to no particular limitation, and examples thereof include a method of coating the surface of the substrate W with the treating liquid, a method of spraying the treating liquid to the surface of the substrate W, and a method of immersing the substrate W in the treating liquid.

Examples of the method of coating the surface of the substrate W with the treating liquid include a method of supplying the treating liquid to a central part of the surface of the substrate W with the substrate W being rotated at a constant speed around the central part as an axis. This causes the treating liquid supplied to the surface of the substrate W to flow from the vicinity of the center of the surface of the substrate W toward the periphery of the substrate W with the centrifugal force generated by the rotation of the substrate W, and the treating liquid spreads over the entire surface of the substrate W. As a result, the entire surface of the substrate W is covered with the treating liquid, and a liquid film of the treating liquid is formed.

The SAM forming step S102 may be performed under an atmosphere of an inert gas, for example.

The SAM forming step S102 may include a step of removing the treating liquid remaining on the surface of the substrate W. The step of removing the treating liquid is subjected to no particular limitation, and examples thereof include a step of shaking off the treating liquid with centrifugal force by rotating the substrate W at a constant speed.

When the step of shaking off the treating liquid with centrifugal force is performed, the rotation speed of the substrate W is subjected to no particular limitation as long as the treating liquid can be sufficiently shaken off. The speed is usually set in the range of 800 rpm to 2500 rpm, preferably 1000 rpm to 2000 rpm, and more preferably 1200 rpm to 1500 rpm.

As shown in FIGS. 2 and 3C, the film forming step S103 is a step of forming a target film 15 on the insulating film 12 in the metal-film-free region. At this time, the SAM 14 formed in the metal-film-forming region functions to mask the metal film 11 as a protective film. This makes it possible to selectively form the target film 15 in the metal-film-free region.

The target film 15 is subjected to no particular limitation, and examples thereof include a film made of aluminum oxide (Al₂O₃), cobalt oxide (CoO), zirconium oxide (ZrO₂), or the like. The method of forming the film 15 made of these oxides is subjected to no particular limitation, and examples thereof include a chemical vapor deposition (CVD) method, an atomic layer deposition (ALD) method, vacuum deposition, sputtering, plating, thermal CVD, and thermal ALD.

The removing liquid preparing step S104 is a step of preparing the removing liquid for example by preparing the removing liquid in such a manner that the removing liquid have its HSP positioned in the first Hansen sphere 1 of the SAM forming material 13 and in the second Hansen sphere 2 of the SAM 14. The removing liquid preparing step S104 is performed at least before the removing step S105 for the SAM 14 to be described later.

The first Hansen sphere 1 of the SAM forming material 13 may be obtained as follows. That is, first, in a Hansen solubility parameter space specified by plotting (δd, δp, δh) in a three-dimensional space, a plurality of organic solvents with known (δd, δp, δh) (excluding a case in which the solvent is a mixed solvent of two or more solvents) are plotted. Next, the solubility of the SAM forming material 13 in each organic solvent is tested. From the results of this test, whether each organic solvent is a good solvent or a poor solvent with respect to the SAM forming material 13 is evaluated. Here, a good solvent is an organic solvent having a better dissolving property or wettability than a poor solvent. With this evaluation, a Hansen sphere containing organic solvents of good solvent and containing no organic solvent of poor solvent, the Hansen sphere having a minimum radius, is specified as the first Hansen sphere 1. Further, the sphere radius R₁ and the center value (δd₁, δp₁, δh₁) are obtained based on the specified first Hansen sphere 1.

The second Hansen sphere 2 of the SAM 14 may be obtained as follows. That is, first, in a Hansen solubility parameter space specified by plotting (δd, δp, δh) in a three-dimensional space, a plurality of organic solvents with known (δd, δp, δh) (excluding a case in which the solvent is a mixed solvent of two or more solvents) are plotted. Next, a wettability test is performed by bringing a droplet of each organic solvent into contact with the surface of the SAM 14 to measure a contact angle. Further, after the measurement of the contact angle, the presence or absence of a solvent mark of the organic solvent on the surface of the SAM 14 is checked. Then, whether each organic solvent is a good solvent or a poor solvent for the SAM 14 is determined from the measurement result of the contact angle and the presence or absence of a solvent mark. With this procedure, a Hansen sphere containing organic solvents of good solvent and containing no organic solvent of poor solvent, the Hansen sphere having a minimum radius, is specified as the second Hansen sphere 2. Further, the sphere radius R₂ and the center value (δd₂, δp₂, δh₂) are obtained based on the specified second Hansen sphere 2.

Next, the removing liquid is prepared. The removing liquid may be prepared by mixing two or more organic solvents such that the HSP is positioned in the region 3 where the first Hansen sphere 1 and the second Hansen sphere 2 overlap each other in the Hansen solubility parameter space. An organic solvent in which its HSP are positioned in the region 3 may be selected and used singly. The mixing ratio in the case of mixing two or more organic solvents is subjected to no particular limitation, and the ratio may be appropriately set according to the HSP and the like of the organic solvents to be used.

As shown in FIGS. 2 and 3D, the removing step S105 is a step of removing the SAM 14 formed in the metal-film-forming region after the step of forming the film 15 is performed. In this step, the removal of the SAM 14 is performed by bringing the removing liquid into contact with at least the SAM 14. As shown in FIG. 3D, this makes it possible to obtain the substrate W in which the film 15 is selectively formed only in the metal-film-free region and the metal film 11 is exposed. Here, the removal of the SAM 14 includes a case where the SAM 14 is detached (peeled) from the substrate W in addition to a case where the SAM is dissolved and removed with the removing liquid. Even in a case where the SAM 14 is peeled off from the substrate W, since the removing liquid of the present embodiment exhibits a good dissolving property with respect to the SAM forming material 13, the SAM 14 after peeling can also be dissolved. This makes it possible to, in the present embodiment, prevent or reduce peeled residues of the SAM 14 from remaining on the surface of the substrate W.

The method of bringing the removing liquid into contact with the SAM 14 is subjected to no particular limitation, and examples thereof include a method of coating surface of the substrate W with the removing liquid, a method of spraying the removing liquid to the surface of the substrate W, and a method of immersing the substrate W in the removing liquid.

Examples of the method of coating the surface of the substrate W with the removing liquid include a method of supplying the removing liquid to a central part of the surface of the substrate W with the substrate W being rotated at a constant speed around the central part as an axis. This causes the removing liquid supplied to the surface of the substrate W to flow from the vicinity of the center of the surface of the substrate W toward the periphery of the substrate W with the centrifugal force generated by the rotation of the substrate W. and the removing liquid spreads over the entire surface of the substrate W. As a result, the entire surface of the substrate W is covered with the removing liquid, and a liquid film of the removing liquid is formed.

The removing step S105 may be performed under an atmosphere of an inert gas, for example.

The removing step S105 may include a step of removing the removing liquid remaining on the surface of the substrate W. The step of removing the removing liquid is subjected to no particular limitation, and examples thereof include a step of shaking off the removing liquid with centrifugal force by rotating the substrate W at a constant speed.

When the step of shaking off the removing liquid with centrifugal force is performed, the rotation speed of the substrate W is subjected to no particular limitation as long as the removing liquid can be sufficiently shaken off. The speed is usually set in the range of 800 rpm to 2500 rpm, preferably 1000 rpm to 2000 rpm, and more preferably 1200 rpm to 1500 rpm.

In this manner, according to the substrate treating method of the present embodiment, by using, as the removing liquid, a removing liquid with a HSP positioned in the first Hansen sphere 1 defined by the HSP of the SAM forming material 13 and in the second Hansen sphere 2 defined by the HSP of the SAM 14, the SAM 14 can be favorably selected and removed while holding down etching of the metal film 11 as compared with a conventional removing liquid.

### (Substrate Treating Apparatus)

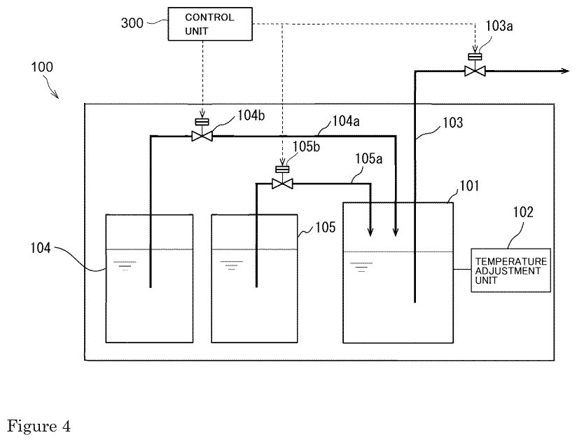

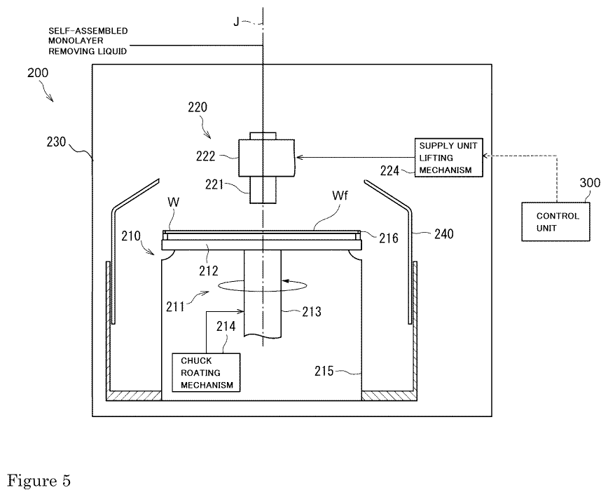

Next, a substrate treating apparatus according to the present embodiment will be described with reference to FIGS. 4 and 5. FIG. 4 is an explanatory diagram schematically showing a supply device of a removing liquid in a substrate treating apparatus according to the embodiment. FIG. 5 is an explanatory diagram schematically showing a removing device in the substrate treating apparatus according to the embodiment.

As shown in FIG. 4, the substrate treating apparatus of the present embodiment includes at least a supply device 100 for supplying a removing liquid, a removing device 200 for removing the SAM 14, and a control unit 300 for controlling each unit of the substrate treating apparatus.

[Supply Device]

As shown in FIG. 4, the supply device 100 according to the present embodiment has a function of supplying a removing liquid for removing the SAM 14 to the removing device 200. The supply device 100 includes a removing liquid tank (storage unit) 101, a temperature adjustment unit 102, and a supply pipe 103.

The removing liquid tank 101 may include a stirring unit (not shown) that stirs the removing liquid in the removing liquid tank 101, and a temperature adjustment unit 102 that adjusts the temperature of the removing liquid in the removing liquid tank 101. Examples of the stirring unit include a unit including a rotation unit that stirs the removing liquid in the removing liquid tank 101 and a stirring control unit that controls the rotation of the rotation unit. The stirring control unit is electrically connected to the control unit 300, and the rotation unit includes, for example, a propeller-like stirring blade at the lower end of a rotation shaft. The control unit 300 gives an operation command to the stirring control unit to rotate the rotation unit, whereby the removing liquid can be stirred by the stirring blade. As a result, the concentration and temperature of the removing liquid can be made uniform in the removing liquid tank 101.

The supply pipe 103 is connected to the removing liquid tank 101 via a pipe line. Further, a valve 103a is provided in a middle path of the supply pipe 103. The valve 103a is electrically connected to the control unit 300, and opening and closing of the valve 103a may be controlled by an operation command of the control unit 300. When the valve 103a is opened by the operation command of the control unit 300, the removing liquid can be supplied to the removing device 200.

The supply device 100 includes a first organic solvent tank 104 that stores the first organic solvent and a second organic solvent tank 105 that stores the second organic solvent. A first discharge pipe 104a for supplying the first organic solvent to the removing liquid tank 101 is connected to the first organic solvent tank 104 via a pipe line. Further, a first valve 104b is provided in a middle path of the first discharge pipe 104a. The first valve 104b is electrically connected to the control unit 300, and opening and closing of the first valve 104b may be controlled by an operation command of the control unit 300. When the first valve 104b is opened by the operation command of the control unit 300, a predetermined amount of the first organic solvent is supplied to the removing liquid tank 101 for preparation of the removing liquid. The first organic solvent tank 104 may include a stirring unit that stirs the stored first organic solvent and a temperature adjustment unit that adjusts the temperature of the first organic solvent (neither shown). As the stirring unit, the same stirring unit as that installable in the removing liquid tank 101 may be used.

A second discharge pipe 105a for supplying the second organic solvent to the removing liquid tank 101 is connected to the second organic solvent tank 105 via a pipe line. Further, a second valve 105b is provided in a middle path of the second discharge pipe 105a. The second valve 105b is electrically connected to the control unit 300, and opening and closing of the second valve 105b may be controlled by an operation command of the control unit 300. When the second valve 105b is opened by the operation command of the control unit 300, a predetermined amount of the second organic solvent is supplied to the removing liquid tank 101 for preparation of the removing liquid. The second organic solvent tank 105 may include a stirring unit that stirs the stored second organic solvent and a temperature adjustment unit that adjusts the temperature of the second organic solvent (neither shown), as in the first organic solvent tank 104.

The supply amount and the supply time of the first organic solvent and the second organic solvent may be adjusted by controlling the opening of the first valve 104b and the second valve 105b with the operation command of the control unit 300. Then, the first organic solvent and the second organic solvent are supplied in a predetermined mixing ratio in the removing liquid tank 101, and as a result, desired removing liquid can be prepared.

In the present embodiment, a case where the removing liquid is prepared using two organic solvents has been described as an example, but the present invention is not limited to this aspect. For example, when a removing liquid composed of one organic solvent is used, the second organic solvent tank 105, the second discharge pipe 105a, and the second valve 105b may be omitted. When three or more organic solvents are used, an organic solvent tank, a discharge pipe, and a valve having the same configuration as above may be further provided.

[Removing Device]

Next, the removing device 200 will be described with reference to FIG. 5.

The removing device 200 according to the present embodiment is a single wafer treating removal device capable of removing the SAM 14 formed on the metal film 11.

As shown in FIG. 5, the removing device 200 includes at least a substrate holding unit 210 that holds the substrate W, a supply unit 220 that supplies a removing liquid to a surface Wf of the substrate W, a chamber 230 that is a container that accommodates the substrate W, and a scattering prevention cup 240 that collects the removing liquid. In addition, the removing device 200 may include a loading/unloading unit (not shown) that loads or unloads the substrate W.

The substrate holding unit 210 is a unit that holds the substrate W. As shown in FIG. 4, the substrate holding unit 210 rotates the substrate W while holding the substrate W in a substantially horizontal orientation with the substrate surface Wf facing upward. The substrate holding unit 210 includes a spin chuck 211 in which a spin base 212 and a rotation support shaft 213 are integrally coupled. The spin base 212 has a substantially circular shape in plan view, and the rotation support shaft 213 having a hollow structure extending in a substantially vertical direction is fixed to a central part of the spin base 212. The rotation support shaft 213 is connected to a rotation shaft of a chuck rotating mechanism 214 including a motor. The chuck rotating mechanism 214 is accommodated in a casing 215 having a cylindrical shape, and the rotation support shaft 213 is rotatably supported by the casing 215 around a vertical rotation axis.

The chuck rotating mechanism 214 may rotate the rotation support shaft 213 around the rotation axis with the driving from a chuck driving unit (not shown) of the control unit 300. This causes the spin base 212 attached to the upper end of the rotation support shaft 213 to rotate around the rotation axis J. The control unit 300 may control the chuck rotating mechanism 214 via the chuck driving unit to adjust the rotation speed of the spin base 212.

In the vicinity of the peripheral edge of the spin base 212, a plurality of chuck pins 216 for gripping the peripheral end of the substrate W are installed upright. The number of chuck pins 216 to be installed is subjected to no particular limitation, but it is preferable to provide at least three chuck pins to reliably hold the substrate W having a circular shape. In the present embodiment, three chuck pins 216 are disposed at equal intervals along the peripheral edge of the spin base 212. Each of the chuck pins 216 includes a substrate support pin that supports the peripheral edge of the substrate W from below, and a substrate holding pin that presses the outer peripheral end surface of the substrate W supported by the substrate support pin to hold the substrate W.

The supply unit 220 is disposed above the substrate holding unit 210 and supplies the removing liquid supplied from the supply device 100 onto the surface Wf of the substrate W. The supply unit 220 includes a nozzle 221 and an arm 222. The nozzle 221 is attached to a distal end of the arm 222 that extends horizontally. The nozzle 221 is disposed above the spin base 212 when the removing liquid is discharged.

The supply unit 220 further includes a supply unit lifting mechanism 224. The supply unit lifting mechanism 224 is connected to the arm 222.

The supply unit lifting mechanism 224 is electrically connected to the control unit 300 and may lift and lower the supply unit 220 in accordance with an operation command from the control unit 300. This causes the nozzle 221 of the supply unit 220 to come close to or separate from the substrate W held by the substrate holding unit 210, and the separation distance between the surface Wf of the substrate W and the nozzle 221 can be adjusted.

When the substrate W is loaded into and unloaded from the removing device 200, the supply unit lifting mechanism 224 is operated with an operation command of the control unit 300 to lift the supply unit 220. This makes it possible to separate the nozzle 221 from the surface Wf of the substrate W to have a certain distance, which enables easy loading and unloading of the substrate W.

The scattering prevention cup 240 is provided to surround the spin base 212. The scattering prevention cup 240 is connected to a lifting drive mechanism (not shown) and can be lifted or lowered in vertical directions. When the removing liquid is supplied to the front surface Wf of the substrate W, the scattering prevention cup 240 is disposed at a predetermined position by the lifting drive mechanism and surrounds the substrate W held by the chuck pin 216 from a side position. This makes it possible to collect the removing liquid scattered from the substrate W and the spin base 212.

In the above description, a case where the removing device in the substrate treating apparatus of the present invention is a single wafer treating type in which the substrate W is processed one by one has been described as an example. However, the substrate treating apparatus of the present invention is not limited to this aspect, and as another aspect of the substrate treating apparatus of the present invention, the substrate treating apparatus of the present invention is also applicable to a batch treating type in which a plurality of substrates are collectively processed.

[Control Unit]

The control unit 300 is electrically connected to each unit of the substrate treating apparatus and controls the operation of each unit. The control unit 300 is configured by a computer including a calculation unit and a storage unit. As the calculation unit, a CPU that performs various types of calculation processing is used. In addition, the storage unit includes a ROM that is a read-only memory for storing a substrate treating program, a RAM that is a readable/writable memory for storing various types of information, and a magnetic disk for storing control software, data, and the like. In the magnetic disk, data related to substrate treating conditions is stored in advance. The substrate treating conditions include, for example, supply conditions of the first organic solvent and the second organic solvent for making the removing liquid have predetermined HSP, and supply conditions of the removing liquid to the substrate W according to the type of the SAM 14 and the like. The CPU reads out the substrate treating conditions into the RAM and controls each unit of the substrate treating apparatus according to the contents.

### (Other Matters)

The supply device and the removing device of the present embodiment may be used in various apparatuses other than the substrate treating apparatus or may be used singly.

In the above description, the most preferred embodiment of the present invention has been described. However, the present invention is not limited to the embodiment. Each configuration in the above-described embodiment and each modification may be changed, modified, replaced, added, deleted, and combined within a range not contradictory to each other.

Hereinafter, preferred examples of the present invention will be exemplarily described in detail. However, the materials, blending amounts, conditions, and the like described in Examples are not intended to limit the scope of the present invention only to those unless otherwise specified.

### Example 1

[Preparation of Treating Liquid]

Octadecylphosphonic acid (CH₃(CH₂)₁₇P(═O)(OH)₂) as an SAM forming material was dissolved in an ethanol solvent to prepare a treating liquid according to the present Example. The concentration of the octadecylphosphonic acid was 0.04 mass % with respect to the total mass of the treating liquid.

[Removing Liquid Preparing Step]

1. Identification of First Hansen Sphere

First, the first Hansen sphere of octadecylphosphonic acid (powder) was obtained. That is, the organic solvents shown in Table 2 below were provided and plotted as organic solvents whose (δd, δp, δh) is known in a Hansen solubility parameter space specified by plotting (δd, δp, δh) in a three-dimensional space.

Next, a solubility test of octadecylphosphonic acid (powder) in each organic solvent was performed. Specifically, 1 mg of octadecylphosphonic acid powder was added to 1 mL of each organic solvent shown in Table 2, and the dissolution state of the octadecylphosphonic acid powder was checked. The test was performed under an environment of 25° C. The dissolution state of the octadecylphosphonic acid powder was determined based on the following criteria.
1: There is no undissolved residue of the octadecylphosphonic acid powder, and there is no fluctuation in the solution.
2: There is no undissolved residue of the octadecylphosphonic acid powder, but there is fluctuation in the solution.
3: There is a undissolved residue of the octadecylphosphonic acid powder.

TABLE 2

| | HSP(MPa^{1/2}) | | | | Dissolving |
|---|---|---|---|---|---|
| Organic solvent | δd | δp | δh | δt | property |
| 1-Butanol | 16.0 | 5.7 | 15.8 | 23.2 | 2 |
| 2-Butanol | 15.8 | 5.7 | 14.5 | 22.2 | 1 |
| Ethylene glycol | 15.9 | 7.2 | 14.0 | 22.4 | 2 |
| monomethyl ether | | | | | |
| Diacetone alcohol | 15.8 | 8.2 | 10.8 | 20.8 | 3 |
| Benzyl alcohol | 18.4 | 6.3 | 13.7 | 23.8 | 1 |
| Ethyl acetate | 15.8 | 5.3 | 7.2 | 18.2 | 3 |
| THF | 16.8 | 5.7 | 8.0 | 19.5 | 1 |
| Methyl isobutyl ketone | 15.3 | 6.1 | 4.1 | 17.0 | 3 |
| 1,4-Dioxane | 17.5 | 1.8 | 9.0 | 19.8 | 3 |
| Acetone | 15.5 | 10.4 | 7.0 | 19.9 | 3 |

Whether each organic solvent was a good solvent or a poor solvent with respect to the octadecylphosphonic acid powder was evaluated based on the results in Table 2. Here, a good solvent is an organic solvent having a better dissolving property or wettability than a poor solvent. Based on the evaluation results, a Hansen sphere containing organic solvents of good solvent and containing no organic solvent of poor solvent, the Hansen sphere having a minimum radius, was specified as the first Hansen sphere 1. Further, the sphere radius R₁ and the center value (δd₁, δp₁, δh₁) were obtained based on the specified first Hansen sphere 1. Obtained results were: (δd₁, δp₁, δh₁)=(16.9±0.2, 5.4±0.5, 11.7±0.3) [MPa^{1/2}], and the sphere radius R₁=3.7 [MPa^{1/2}].

2. Identification of Second Hansen Sphere

Subsequently, the second Hansen sphere of a monolayer of octadecylphosphonic acid was obtained. That is, the organic solvents shown in Table 3 below were provided and plotted as organic solvents whose (δd, δp, δh) is known in a Hansen solubility parameter space specified by plotting (δd, δp, δh) in a three-dimensional space.

Next, a droplet of each organic solvent was brought into contact with the surface of the monolayer of octadecylphosphonic acid to measure a contact angle, and a wettability test was performed. Specifically, each organic solvent shown in Table 3 was dropped onto a monolayer of octadecylphosphonic acid, and the contact angle was measured. A contact angle meter (Trade name: Drop Master 501, manufactured by Kyowa Interface Science Co., Ltd.) was used to measure the contact angle. The results are shown in Table 3. In addition, after the measurement of the contact angle, the presence or absence of a solvent mark of the organic solvent on the surface of the monolayer of octadecylphosphonic acid was checked. As a result, no solvent mark was confirmed with any of the organic solvents.

From the measurement results of the contact angles and the presence or absence of solvent marks in Table 3, whether each organic solvent was a good solvent or a poor solvent with respect to the monolayer of octadecylphosphonic acid was evaluated. Based on the evaluation results, a Hansen sphere containing organic solvents of good solvent and containing no organic solvent of poor solvent, the Hansen sphere having a minimum radius, was specified as the second Hansen sphere 2. Further, the sphere radius R₂ and the center value (δd₂, δp₂, δh₂) were obtained based on the specified second Hansen sphere 2. Obtained results were: (δd₂, δp₂, δh₂)=(16.4±0.7, 6.1±1.2, 0.0±2.0) [MPa^{1/2}], and the sphere radius R₂=10.2 [MPa^{1/2}].

TABLE 3

| | HSP(MPa^{1/2}) | | | | Contact |
|---|---|---|---|---|---|
| Organic solvent | δd | δp | δh | δt | angle |
| 1-Methylnaphthalene | 19.7 | 0.8 | 4.7 | 20.3 | 60.7º |
| N-methyl-2-pyrrolidone | 16.8 | 2.8 | 6.7 | 18.3 | 66.0° |
| 1-Bromonaphthalene | 20.6 | 3.1 | 4.1 | 21.2 | 66.6° |
| Nitrobenzene | 20.0 | 12.7 | 4.0 | 24.0 | 65.9° |
| Benzyl alcohol | 18.4 | 6.3 | 13.7 | 23.8 | 68.7° |
| N,N-dimethylformamide | 17.4 | 13.7 | 11.3 | 24.9 | 68.1º |
| Benzyl benzoate | 20.0 | 5.1 | 5.2 | 21.3 | 69.1º |
| Quinoline | 20.5 | 5.6 | 5.7 | 22.0 | 68.9° |
| Dimethyl sulfoxide | 18.4 | 16.4 | 10.2 | 26.7 | 74.1° |
| γ-Butyrolactone | 18.0 | 16.6 | 7.4 | 25.6 | 72.8° |

3. Provision of Removing Liquid

Based on the first Hansen sphere of octadecylphosphonic acid and the second Hansen sphere of the monolayer of octadecylphosphonic acid, (δd, δp, δh) positioned at the center of the circle formed by the intersection of these Hansen spheres was identified. As a result, it was found that the optimum removing liquid for removing the monolayer of octadecylphosphonic acid was the removing liquid with HSP (δd, δp, δh)=(16.8, 5.6, 9.0) [MPa^{1/2}] and δt=19.9 [MPa^{1/2}].

Further, based on this result, THF was selected as a removing liquid according to the present Example. HSP of THF is (δd, δp, δh)=(16.8, 5.7, 8.0) [MPa^{1/2}], δt=19.5 [MPa^{1/2}].

[SAM Forming Step and Film Forming Step]

A SAM was formed on a surface of a substrate by using the above-mentioned treating liquid. Specifically, first, a substrate having an interlayer insulating film composed of an SiO₂ film (film thickness: 200 nm) in which a trench having a wiring width of 100 nm is formed and having a Cu film (film thickness: 200 nm) as a metal film embedded in the trench was provided (substrate preparing step S101).

Next, the surface of the substrate was coated with the treating liquid to form a SAM in which octadecylphosphonic acid was adsorbed on the Cu film (SAM forming step S102).

Further, an aluminum oxide (Al₂O₃) film was formed on the SiO₂ film by an ALD method using H₂O as an oxidizing agent. Specifically, an organic metal of Al was deposited as one layer in an atomic layer level thickness, and then Al was oxidized with the oxidizing agent to form a thin film of Al₂O₃. This step was repeated 72 times. An Al₂O₃ film having a thickness of 5 nm was thus formed.

[SAM Removing Step]

Subsequently, the removing liquid was supplied to the surface of the substrate, and the SAM was removed by bringing the removing liquid into contact with the SAM on the Cu film. A sample according to this Example was thus produced.

### Example 2

In this Example, 2-butanol was used as a removing liquid in place of THF. A sample according to the present Example was produced in the same manner as in Example 1 except for the above.

### Example 3

In this Example, benzyl alcohol was used as a removing liquid in place of THF. A sample according to the present Example was produced in the same manner as in Example 1 except for the above.

### Example 4

In this Example, 1-pentanol was used as a removing liquid in place of THF. A sample according to the present Example was produced in the same manner as in Example 1 except for the above.

### Example 5

In this Example, I-butanol was used as a removing liquid in place of THF. A sample according to the present Example was produced in the same manner as in Example 1 except for the above.

### Example 6

In the present Example, a mixed solvent composed of THF, 2-butanol, and benzyl alcohol was used as a removing liquid in place of THF. The mixing ratio of THF, 2-butanol, and benzyl alcohol was set to THF:2-butanol: benzyl alcohol=8:1:1 in a volume ratio. A sample according to the present Example was produced in the same manner as in Example 1 except for the above.

### Example 7

In the present Example, a mixed solvent composed of THF, 1-butanol, and benzyl alcohol was used as a removing liquid in place of THF. The mixing ratio of THF, 1-butanol, and benzyl alcohol was set to THF: 1-butanol:benzyl alcohol=8:1:1 in a volume ratio. A sample according to the present Example was produced in the same manner as in Example 1 except for the above.

### Example 8

In the present Example, a mixed solvent composed of THF, 1-pentanol, and benzyl alcohol was used as a removing liquid in place of THF. The mixing ratio of THF, 1-pentanol, and benzyl alcohol was set to THF: 1-pentanol:benzyl alcohol=8:1:1 in a volume ratio. A sample according to the present Example was produced in the same manner as in Example 1 except for the above.

### (Evaluation of Removing Performance)

In each of the samples of Examples 1 to 8, how much Cu film etching was held down before and after the removal of the SAM was checked. Specifically, the film thickness of the Cu film before and after removal of the SAM was measured by transmission electron microscope (TEM) observation, and the amount of decrease in the film thickness of the Cu film was calculated. The results are shown in Table 4. As can be seen from Table 4, in any of the samples of Examples 1 to 8, the decrease amount of the film thickness of the Cu film was able to be held down to a decrease amount of 3 nm or less with respect to the initial film thickness of 200 nm. From the results, it was confirmed that all the removing liquids used in Examples 1 to 8 were capable of removing the SAM while holding down Cu film etching as much as possible, and they were excellent in selective removal performance.

Further, in each of the samples of Examples 1 and 6, the residue ratio of Al atoms on the Cu film after removal of the SAM was also checked. Specifically, for each sample, elemental analysis in an observation region was performed by energy dispersive X-ray spectroscopy (EDX) while an image of a section of each sample was observed with TEM. Elemental analysis by EDX targeted Al atoms in the Al₂O₃ film and the Cu film. Further, the residue ratio of Al atoms on the Cu film was calculated based on the following formula. The results are shown in Table 4.

(Residue ratio of Al atom)=(Al atomic weight on Cu film)/(Al atomic weight in Al₂O₃ film)×100(%)

In the sample of Example 6, the residue ratio of Al atoms was able to be held down to 10% or less. Al atoms remain in the SAM because of the formation of the Al₂O₃ film. Thus, it can be said that the smaller the Al atom residue in the Cu film after removal of the SAM, the better the SAM is selectively removed from the Cu film. In the sample of Example 6, since the residue ratio of Al atoms on the Cu film is held down, it can be said that the removing liquid used in Example 6 is excellent in removing SAM.

TABLE 4

| | Example | Example | Example | Example | Example | Example | Example | Example |
|---|---|---|---|---|---|---|---|---|
| | 1 | 2 | 3 | 4 | 5 | 6 | 7 | 8 |
| Residue ratio of Al | 15.7 | — | — | — | — | 5.1 | — | — |
| atoms on Cu film | | | | | | | | |
| (%) | | | | | | | | |
| Loss amount of Cu | 0.2 | 0.4 | 0.3 | 0.5 | 0.4 | 0.2 | 0.2 | 0.4 |
| film (nm) | | | | | | | | |

1. A self-assembled monolayer removing liquid for selectively removing a self-assembled monolayer provided on a surface of a substrate,
the self-assembled monolayer removing liquid having a Hansen solubility parameter positioned in a first Hansen sphere of a material for forming the self-assembled monolayer and in a second Hansen sphere of the self-assembled monolayer, the first Hansen sphere being defined by a center value (δd₁, δp₁, δh₁) [MPa^{1/2}] and a sphere radius R₁ [MPa^{1/2}] in a Hansen solubility parameter space, the second Hansen sphere being defined by a center value (δd₂, δp₂, δh₂) [MPa^{1/2}] and a sphere radius R₂ [MPa^{1/2}] in the Hansen solubility parameter space.

2. The self-assembled monolayer removing liquid according to claim 1, wherein the Hansen solubility parameter of the self-assembled monolayer removing liquid has a value positioned at a center of a circle formed by an intersection of the first Hansen sphere and the second Hansen sphere or has a value positioned at a contact point between the first Hansen sphere and the second Hansen sphere.

3. The self-assembled monolayer removing liquid according to claim 1, wherein
the material for forming the self-assembled monolayer is octadecylphosphonic acid,
the self-assembled monolayer includes a monolayer of the octadecylphosphonic acid,
the first Hansen sphere is defined by the center value (δd₁, δp₁, δh₁)=(16.9±0.2, 5.4±0.5, 11.7±0.3) [MPa^{1/2}] and the sphere radius R₁=3.7 [MPa^{1/2}] in the Hansen solubility parameter space, and
the second Hansen sphere is defined by the center value (δd₂, δp₂, δh₂)=(16.4±0.7, 6.1±1.2, 0.0±2.0) [MPa^{1/2}] and the sphere radius R₂=10.2 [MPa^{1/2}] in the Hansen solubility parameter space.

4. The self-assembled monolayer removing liquid according to claim 1, wherein the self-assembled monolayer removing liquid is at least one organic solvent selected from a group consisting of 1-butanol, 2-butanol, 1-pentanol, tetrahydrofuran, and benzyl alcohol.

5. A substrate treating method for treating a substrate provided with a self-assembled monolayer on a surface, the method comprising:
a preparing step of preparing a self-assembled monolayer removing liquid for selectively removing the self-assembled monolayer from the substrate; and
a removing step of bringing the self-assembled monolayer removing liquid into contact with the self-assembled monolayer and selectively removing the self-assembled monolayer from the substrate,
wherein
the preparing step is a step of preparing the self-assembled monolayer removing liquid having a Hansen solubility parameter positioned in a first Hansen sphere of a material for forming the self-assembled monolayer and in a second Hansen sphere of the self-assembled monolayer, the first Hansen sphere being defined by a center value (δd₁, δp₁, δh₁) [MPa^{1/2}] and a sphere radius R₁ [MPa^{1/2}] in a Hansen solubility parameter space, the second Hansen sphere being defined by a center value (δd₂, δp₂, δh₂) [MPa^{1/2}] and a sphere radius R₂ [MPa^{1/2}] in the Hansen solubility parameter space.

6. The substrate treating method according to claim 5, wherein the preparing step is a step of preparing the self-assembled monolayer removing liquid to cause the Hansen solubility parameter of the self-assembled monolayer removing liquid to have a value positioned at a center of a circle formed by an intersection of the first Hansen sphere and the second Hansen sphere or have a value positioned at a contact point between the first Hansen sphere and the second Hansen sphere.

7. The substrate treating method according to claim 5, wherein
the material for forming the self-assembled monolayer is octadecylphosphonic acid,
the self-assembled monolayer includes a monolayer of the octadecylphosphonic acid,
the first Hansen sphere is defined by the center value (δd₁, δp₁, δh₁)=(16.9±0.2, 5.4±0.5, 11.7±0.3) [MPa^{1/2}] and the sphere radius R₁=3.7 [MPa^{1/2}] in the Hansen solubility parameter space, and
the second Hansen sphere is defined by the center value (δd₂, δp₂, δh₂)=(16.4±0.7, 6.1±1.2, 0.0±2.0) [MPa^{1/2}] and the sphere radius R₂=10.2 [MPa^{1/2}] in the Hansen solubility parameter space.

8. The substrate treating method according to claim 5, wherein the self-assembled monolayer removing liquid is at least one organic solvent selected from a group consisting of 1-butanol, 2-butanol, 1-pentanol, tetrahydrofuran, and benzyl alcohol.

9. A substrate treating apparatus for treating a substrate provided with a self-assembled monolayer on a surface, the substrate treating apparatus comprising:
a storage unit that stores a self-assembled monolayer removing liquid for selectively removing the self-assembled monolayer;
a supply unit that supplies the self-assembled monolayer removing liquid to a surface of the substrate and selectively removes the self-assembled monolayer from the surface of the substrate; and
a control unit that controls supply of the self-assembled monolayer removing liquid to the surface of the substrate,
wherein
the control unit prepares, in the storage unit, as the self-assembled monolayer removing liquid, a self-assembled monolayer removing liquid having a Hansen solubility parameter positioned in a first Hansen sphere of a material for forming the self-assembled monolayer and in a second Hansen sphere of the self-assembled monolayer, the first Hansen sphere being defined by a center value (δd₁, δp₁, δh₁) [MPa^{1/2}] and a sphere radius R₁ [MPa^{1/2}] in a Hansen solubility parameter space, the second Hansen sphere being defined by a center value (δd₂, δp₂, δh₂) [MPa^{1/2}] and a sphere radius R₂ [MPa^{1/2}] in the Hansen solubility parameter space.
